(19) United States
(12) Patent Application Publication
(10) Pub. No.: US 2017/0118869 A1
(43) Pub. Date: Apr. 27, 2017

(54) SUBSEA COOLING ASSEMBLY

(71) Applicant: FMC Kongsberg Subsea AS, Kongsberg (NO)

(72) Inventor: Stein Følkner, Østerås (NO)

(21) Appl. No.: 15/317,966

(22) PCT Filed: Jun. 5, 2015
(86) PCT No.: PCT/EP2015/062535

§ 371 Date: Dec. 11, 2016

(30) Foreign Application Priority Data
Jun. 11, 2014 (NO) 20140733

(51) Int. Cl. H05K 7/20

(52) U.S. Cl. CPC H05K 7/20236; H05K 7/209; H05K 7/20927; H05K 7/20336; H05K 7/20409

(57) ABSTRACT

A subsea cooling assembly has a block module for the accommodation of electronics or power components and a cover element. The block module is arranged with at least one recess, with the electronics or power components being arranged in the at least one recess of the block module for the transfer heat between the electronics or power components and the surrounding sea through the block module. The cover element has outer rim portions arranged to fit with outer rim portions of the at least one recess for closing off the interior of the at least one recess. The block module has at least one strength supporting structure arranged to provide load support to at least a portion of the cover element which is distanced away from the outer rim portions of the cover element.

The invention concerns a subsea cooling assembly, and a subsea system including at least two subsea cooling assemblies.

In accordance with the invention, the subsea cooling assembly is applied for the cooling of electronics or power components. The electronics or power components may be used for controlling or manipulating the characteristics of a motor. For instance, the electronics or power components may comprise a variable speed drive employed to control the speed of a motor of a compressor, a water pump, a fan or other devices wherein a variable speed motor may be used for varying the speed of the motor.

Typical electronics or power components for enclosure in the subsea cooling assembly in accordance with the invention may include IGBTs, MOSFETs, diodes, thyristors, GTOs, inductors, transformers, resistors, capacitors, gate drivers, power supplies, batteries, control electronics, etc.

### FIELD OF THE INVENTION

One field of use for the subsea cooling assembly in accordance with the invention is a subsea application such as for instance a subsea pump application, and more specifically a variable speed drive for a subsea pump application. As some of the electronic components used in variable speed drives have high thermal losses, an efficient cooling of the electronic or power components in these circumstances is necessary for the efficient working and reliability of the system. The subsea cooling assembly in accordance with the invention may also be applied to other passive cooled subsea power modules, e.g. amplifiers for magnetic bearing systems, power supplies, UPS modules, FACTS (Flexible Alternating Current Transmission Systems) modules, HVDC modules, SMART GRID modules or even the sort of actively cooled system where seawater is pushed past the cooling assembly according to the invention.

Consequently it is desirable to provide a reliable and effective concept for cooling of power or electronic components in atmospheric enclosures for use in a subsea variable speed drive system. As the need for a simpler and more efficient cooling of power or electronic components also has other fields of use than in a subsea variable speed drive, it is an object of the invention to provide an efficient cooling arrangement for power or electronic components which is applicable for subsea use as such.

### BACKGROUND OF THE INVENTION

Various systems are known for the cooling of electronic or power components to be used subsea. In some cooling systems, a cooling arrangement is provided for the active cooling of the electronic or power components arranged inside an housing. Other cooling systems include passive cooling of subsea electronic components utilizing the surrounding seawater as a cooling medium, by heat conduction through the pressure shell, preferably a cylindrical pressure shell, and heat convection to ambient seawater. A problem with this system that still has to been solved is how to ensure the efficient transfer of heat between the electronic or power components and the seawater.

One prior art solution for passive cooling of electronic or power components which are arranged inside a 1 atmosphere enclosures comprises mounting of the components on heat sinks having an outer curvature that matches the inner diameter of a cylindrical pressure housing. The heat sinks are installed in the housing and the required contact pressure between the heat sink and the housing is provided by an expansion mechanism or by the use of bolts. This solution has several disadvantages: the heat from the power components needs to be transferred through a number of heat conducting elements that are arranged in series and out to the seawater and this is not very efficient. Further, as the electronic or power component needs to be installed inside the cylindrical housing, the cylindrical housing must be provided with a certain size to make the installation possible. Also, the surfaces of the cylindrical housing need to match the curvature of the heat sink to make sure that the heat transfer occurs efficiently, and this requires accurate machining when manufacturing the matching surfaces of the cylindrical housing and the heat sink.

As mentioned above, it is well known within the field to provide the heat sink device as a cylindrical shaped pressure housing and to use heat sink segments internally to transfer heat from the electronic or power components to the pressure shell. Currently, variable speed drives to be used subsea are being developed using active cooling. In accordance with this development a coolant fluid is circulated in a closed circuit that transports heat from the active components inside the enclosure to a natural convection cooler externally of the enclosure. This solution provides effective cooling but adds complexity and increases the number of failure modes compared to a passive system. An example of an assembly for cooling of electronic components using an electrically conductive coolant is described in EP 2645839.

The prior art also includes a solution with a rectangular pressure housing for submerged electronics. In WO 2012/158289, a rectangular box with power electronics positioned in grooves in the bottom and a plate at the open end is disclosed. However, the plate at the top will buckle at higher pressures as it is not supported otherwise than along the outer rim.

Another example of a cooling arrangement is shown in WO 01/08218. This publication discloses an open framed assembly of semiconductor devices which are arranged with a cooling arrangement and provided so that it is self cleaning.

It is an object of the invention to provide a subsea cooling assembly using the surrounding seawater as a cooling medium and ensuring that the transfer of heat between the electronic or power components is efficient, while at the same time providing a subsea cooling assembly which is able to withstand the pressure load occurring at considerable sea depths. It is a further object of the invention to provide a subsea cooling assembly which makes an easy installation of power and electronic components possible.

The cooling assembly for cooling using ambient sea water in accordance with the invention combines the possibility of easy access to the installation area for accommodation of the components with an overall stiffness of the cooling assembly to endure ambient pressure, such as hydrostatic pressure.

The basic idea for the invention is to provide a pressure housing which is preferably non-cylindrical and which allows mounting of the power components directly to the pressure boundary. The cooling assembly in accordance with the invention will reduce the number of thermal contact resistances and thereby potentially reduce the total thermal resistance between the heat source and ambient seawater. Further, the cooling assembly is provided with additional support compared to prior art solutions to prevent critical deformation of the pressure shell. The cooling assembly in accordance with the invention is configured for a more optimized assembly process, as the layout provides unobstructed access for mounting and wiring electronic and power components in the cooling assembly.

### SUMMARY OF THE INVENTION

The subsea cooling assembly according to the invention comprises a block module for the accommodation of electronics or power components and a cover element. The block module is arranged with at least one recess and the electronics or power components are arranged in the at least one recess of the block module for the transfer of heat between the electronics or power components and the surrounding sea through the block module. The cover element has outer rim portions arranged to fit with outer rim portions of the at least one recess for closing off the interior of the at least one recess. The block module has at least one strength supporting structure arranged to provide load support to at least a portion of the cover element which is distanced away from the outer rim portions of the cover element.

The outer rim portions of the at least one recess may be located close to outer rim portions of the block module or further away from the outer rim portions of the block module, depending on the configuration, position and the number of the recess(es). In one aspect the recess(es) may be provided with a slanting configuration wherein portions of the outer rim portions of the recess(es) closer to the outer rim portions of the block module are nearer to the cover element when installed, whereas other portions of the recess(es) further away from the outer rim portions of the block module are further away from the installed cover element. Also, the recess(es) may be shaped so that the outer rim portions of the recess essentially coincide with the outer rim portions of the block module.

Thus, the at least one strength supporting structure may be arranged to offer support to any portion of the cover element in between the outer rim portions of the cover element. Such supporting structure may comprise portions close to the outer rim portions of the cover element, positioned at a mid-area in between the outer rim portions, or a continuous portion extending across from one outer rim portion of the cover element to an outer rim portion at another side of the cover element.

The at least one strength supporting structure may be arranged extending in a transverse direction across the block module from one side portion of the block module to an opposing side portion of the block module. The side portion of the block module may coincide with the outer rim portions of the block module or may be distanced somewhat away from the rim portions. The at least one strength supporting structure may be arranged extending in a transverse direction across the at least one recess from one side portion of the block module to an opposing side portion of the block module.

The at least one strength supporting structure may define at least an inner wall of a recess. The recess may then be divided into two separate compartments. Two strength supporting structures may be arranged at each side of a recess extending across from a side portion of the block module to another side portion of the block module, wherein each supporting structure defines oppositely arranged inner walls of a recess or a compartment of a recess. In the case where the block module is arranged with plural recesses or compartments of a recess, a number of strength supporting structures may define the recesses or compartments of the recesses. The number of recesses and strength supporting structures may vary, as well as the configuration, dimension and orientation of the individual strength supporting structures and the recesses in order to provide the cooling assembly with an easy access for installation and sufficient strength support to endure the applied load at a specific sea depth and at a chosen application or field of use.

The hyperbaric pressure load on the block module and cover element is taken by the at least one strength supporting structure in compression between the block module and cover element. When the block module is provided with more than one strength supporting structure, the spacing between them may vary. In one aspect the maximum spacing between the strength supporting structures is limited by the allowed deflection of the mounting surface for the electronic and power components and the stiffness of the subsea cooling assembly, which may be provided by the combined stiffness of the block module and the cover element mounted to the block module.

The electronics or power components may be positioned on a mounting surface of the at least one recess. The electronics or power components may be mounted directly or indirectly to the mounting surface in a manner that allows for satisfactory transfer of heat from the electronics or power components to the block module. The mounting surface may be any of the surfaces of the recess, and in one aspect the bottom surface of the recess may serve as a mounting surface, thereby facilitating the installation of the power and electronic components into the recess.

The exterior of the block module may be provided with at least one cooling rib to enhance the cooling effect of the cooling assembly. In one aspect the longitudinal direction of the cooling rib may be perpendicular to the direction of the strength supporting structure across the block element. The combination of the strength supporting structure and the cooling ribs arranged perpendicular to the strength supporting structure provides the cooling assembly with an overall stiffness suitable for withstanding pressure loads when submerged at considerable sea depths. The overall stiffness of the cooling arrangement may also be improved by increasing the thickness of the block module and the cover element.

In addition or as an alternative to the cooling ribs, the block module may be provided with a cooling arrangement comprising at least one cooling pipe element to increase the cooling effect of the cooling assembly.

In some circumstances a load bearing surface of the strength supporting structure is arranged in contact with portion(s) of the cover element when the cover element is arranged in a position closing off the interior of the at least one recess.

The cover plate is arranged to close off the interior of the recesses from the surrounding water when placed onto the block module. In this closed position the cover plate may be welded onto the block module or joined to the block module using other sealing off methods, for instance by employing gaskets in the sealing surface between the block module and the cover element.

The block module and the at least one strength supporting structure may be provided as one piece, or the block module and the at least one strength supporting structure may be provided as separate elements manufactured in the same or different material. As the block module is arranged to transfer heat from the power or electronic components to the surrounding sea water, it may be advantageous to manufacture the block module in a material of high thermal conductivity. The block module may be casted or forged, and the recesses of the block module may thereafter be machined or produced directly in the casting process, wherein the material which surrounds the individual recess makes up the at least one strength supporting structure. Alternatively, the block module can be configured for the later installment of the at least one strength supporting structure to be connected to the block thereby providing at least one recess. The block module may of course also be provided by the combination of pre-manufactured recesses and later installed supporting structures.

The cover element and the block module may be shaped as plate structures, with squared cross sections arranged to fit the cover element onto the block. The cover element and the block module may of course also be provided with other configurations than plate structures with a squared cross section.

As an alternative to using the cover element for closing off the interior of the recesses, the cover element may be provided by another block module which is arranged to fit onto the first block module.

The invention also includes a subsea cooling system comprising the connection of at least two cooling assemblies. In accordance with the invention it is possible to connect a number of cooling assemblies to form a modularized system. In such a system a cooling assembly may be used for each phase in a VSD, or split redundant functions into A and B power modules. The cooling assemblies may be connected by steel tubes or oil filled cable hoses.

High pressure feed-through penetrators will typically be installed in the heat sink part of the enclosure. Wiring between the components and termination to the penetrators can thus be completed before the cover element is mounted and allows for function testing of the cooling assembly before the interior of the recesses is closed off, for instance by seal welding of the cover.

### BRIEF DESCRIPTION OF THE DRAWING

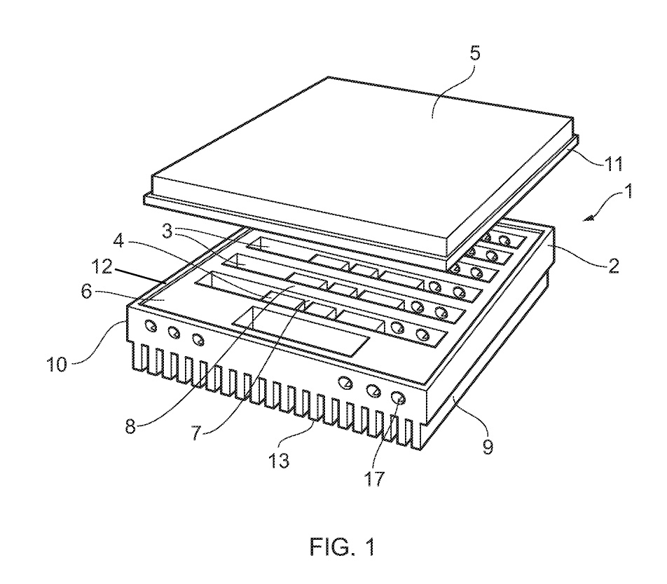

In the following description, an example of one embodiment of the invention will be described in more detail with reference to FIG. 1, which is a perspective view of an embodiment of the invention.

### DETAILED DESCRIPTION OF THE INVENTION

FIG. 1 shows an example of a subsea cooling assembly 1 in accordance with the invention, wherein a block module 2 has a recessed surface 6 arranged with a number of recesses 3 for accommodating electronics or power components 4. The electronics or power components 4 are placed in the recesses 3 in direct or indirect contact with a component mounting surface of the recess, for instance the bottom surface of the recess. In FIG. 1, the recesses 3 are shown having essentially equal size and are spaced side by side in a parallel relationship with essentially an equal distance between the recesses. However, the configuration and dimensions of the recesses may vary according to the kind of electronics or power components 4 to be accommodated in the recesses.

Each recess 3 may have an oblong shape as illustrated in FIG. 1 with a length extending from one side portion 9 to an oppositely arranged side portion 10, and each recess may be arranged with a varying or uniform depth. The size and shape of the opening of the recess 3 into the recessed surface 6 may vary. When the recessed surface 6 is provided with plural recesses 3 as shown in FIG. 1, the size, configuration and orientation of the recesses may vary from one recess to the other or may be the same.

A cover element/cover plate 5 is provided to be arranged onto the block module 2 to close off the interior of the recesses 3 from the surrounding water. The cover plate may be welded onto the block module 2 or otherwise joined to the block module in order to seal off the interior of the recesses 3 of the block module. As seen in the figure, the block module 2 is arranged with an outer rim portion 12 which is arranged to fit with an outer rim portion 11 of the cover element 5.

The cooling of the electronics or power components 4 located in the recesses 3 occurs by passive cooling by the transfer of heat through the material of the block module 2 as the exterior of the block assembly is exposed to sea water. In the example shown in FIG. 1, the block module 2 is shown as a machined block which may be manufactured in a material of high thermal conductivity to enhance the transfer of heat through the block module 2 and arrange for an efficient cooling of the electronics or power components 4. The recesses 3 are provided to facilitate the installment of the electronics or power components 4 into the block module 2 and to ensure efficient cooling through the block module 2.

As the subsea cooling assembly 1 is to be used at considerable sea depths, the subsea cooling assembly 1 is arranged to endure hyperbaric pressures working on the block module 2 and the cover plate 5 at these sea depths. In order to provide the subsea cooling assembly with a stiffness for withstanding the pressures on the block module 2 and the cover plate 5, the block module 2 has at least one strength supporting structure 7 which in FIG. 1 is shown as a rib structure. The strength supporting structure 7 has a load bearing surface 8 and is arranged to extend transversely across the block module 2 from the side portion 9 to the oppositely arranged side portion 10. As the block module 2 in this embodiment is shown as a plate structure, the oppositely arranged side portions are here constituted by the side surfaces of the plate. When the cover plate 5 is arranged onto the block module 2 so that the outer rim 11 of the cover plate is arranged to fit onto the outer rim 12 of the block module 2, at least one portion of the cover plate 5 distanced away from the outer rim portions of the cover element is supported by a load bearing surface 8 of the strength supporting structure 7.

In the embodiment of the block module as shown in FIG. 1, a plurality of strength supporting structures 7 are provided side by side to ensure an evenly distributed support over the surface of the cover element 5 facing the block module 2. The spacing between the strength supporting structures 7 determines the stiffness of the base module, and the maximum allowed spacing is determined by the deflection of the component mounting surface (not shown) in the recess 3. The strength supporting structures 7 may constitute the inner walls of the recess extending from one side surface of the block module 2 to the other side surface. As explained above when describing the recesses, the configuration, dimension and orientation of the individual strength supporting structures 7 may vary, and the strength supporting structures 7 may be uniform or non uniform in the direction transversely across the block module 2. The load bearing surfaces 8 of the strength supporting structures 7 may be arranged so that contact is established with corresponding portions of the cover element 5 when the cover element is brought into the closed position, or the load bearing surfaces 8 may be distanced from the corresponding portions of the cover element 5 but dimensioned so that contact is established at specific ambient pressure conditions.

The strength supporting structure(s) 7 may be provided as an integrated part of the block module 2, wherein the strength supporting structure(s) 7 and the block module 2 are made in one piece, ensuring an efficient heat transfer between the components located in the recesses 3 and the sea water surrounding the block module 2. Alternatively, the strength supporting structure(s) 7 may be provided separately from the block module 2 and arranged to be connected to the block module 2. The strength supporting structure(s) 7 may then be provided in the same or different material as the block module 2.

The sea water surrounding the block module 2 serves as the cooling medium for cooling the components located in the recesses 3. To optimize the heat exchange between the sea water and the block module 2, the exterior of the block module may be provided with a structure allowing efficient interface contact between the block module and the sea water. In this respect the block module may be provided with cooling ribs or cooling fins 13 extending in a direction which is perpendicular to the transversally arranged strength supporting structures 7. The orientation of the cooling ribs 13 perpendicular to the strength supporting structures 7 increases the overall stiffness of the block module 2. The combination of the strength supporting structures 7 and cooling fins 13 being arranged perpendicular to each other, and the increase of the thickness of the base module 2 and the cover plate, provides the subsea cooling assembly with a possibility of three axis stiffness control. If needed, the thickness of the cover plate 5 and the plate shaped block module 2 may also be increased.

The cooling fins 13 are shown as integral parts of the block module 2, but the cooling fins 13 may of course also be provided as addition equipment to be attached to the block module 2. In addition or as an alternative to the cooling ribs 13, a cooling arrangement such as a cooling pipe element may be provided.

In FIG. 1 the cover element 5 and the block module 2 are shown as plate structures, with squared cross sections arranged to fit the cover element onto the block, but the cover element 5 and the block module 2 may as the skilled person will realize also have other configurations. Even if the cooling assembly may be given various configurations, it will be advantageous to the cooling effect that the cooling assembly is shaped so that the exterior has a large surface and a large ratio between the exterior surface and the volume of the cooling assembly.

Installation holes 17 are shown for the insert of penetrators such as high pressure feed-through penetrators (not shown).

In an embodiment the cover element 7 may be substituted with another block module arranged onto the block module 2 to close off the interior of the recess(es).

The subsea cooling assembly 1 may be connected with other cooling assemblies to produce a modularized cooling system.

In the preceding description, various aspects of the apparatus according to the invention have been described with reference to the illustrative embodiment. For purposes of explanation, specific numbers, systems and configurations were set forth in order to provide a thorough understanding of the apparatus and its workings. However, this description is not intended to be construed in a limiting sense. Various modifications and variations of the illustrative embodiment, as well as other embodiments of the apparatus, which are apparent to persons skilled in the art to which the disclosed subject matter pertains, are deemed to lie within the scope of the present invention as defined in the in the attached claims.

1. A subsea cooling assembly comprising:
a block module which is configured to accommodate a number electronics or power components, the block module comprising at least one recess in which the electronics or power components are arranged for the transfer heat between the electronics or power components and the surrounding sea through the block module; and
a cover element comprising outer rim portions which are configured to fit with outer rim portions of the at least one recess for closing off the interior of the at least one recess;
wherein the block module comprises at least one strength supporting structure which is configured to provide load support to at least a portion of the cover element which is distanced away from the outer rim portions of the cover element.

2. The subsea cooling assembly in accordance with claim 1, wherein the at least one strength supporting structure is extends in a transverse direction across the block module from one side portion of the block module to an opposite side portion of the block module.

3. The subsea cooling assembly in accordance with claim 1, wherein the at least one strength supporting structure is defined by at least an inner wall of the at least one recess.

4. The subsea cooling assembly in accordance with claim 1, wherein the electronics or power components are positioned on a mounting surface which is located in the at least one recess.

5. The subsea cooling assembly in accordance with claim 2, wherein the exterior of the block module is provided with at least one cooling rib.

6. The subsea cooling assembly in accordance with claim 5, wherein the at least one cooling rib extends in a longitudinal direction which is perpendicular to the direction of the strength supporting structure.

7. The subsea cooling assembly in accordance with claim 1, wherein the block module includes a cooling arrangement comprising at least one cooling pipe element.

8. The subsea cooling assembly in accordance with claim 1, wherein the strength supporting structure comprises a load bearing surface which is configured to contact the cover element when the cover element is in a position to close off the the at least one recess.

9. The subsea cooling assembly in accordance with claim 1, wherein the block module and the at least one strength supporting structure comprises separate parts of a single structure.

10. The subsea cooling assembly in accordance with claim 1, wherein the cover element and the block module are shaped as plate structures comprising squared cross sections which are configured to fit together.

11. The subsea cooling assembly of claim 1, wherein the cover element comprises a second block module.

12. The subsea cooling system of claim 1, further comprising a second such cooling assembly, wherein the cooling assemblies are connected together.
